(19) United States
(12) Patent Application Publication
(10) Pub. No.: US 2009/0197086 A1
(43) Pub. Date: Aug. 6, 2009

(54) ELIMINATION OF PHOTORESIST MATERIAL COLLAPSE AND POISONING IN 45-NM FEATURE SIZE USING DRY OR IMMERSION LITHOGRAPHY

(76) Inventors: Sudha Rathi, San Jose, CA (US); Eui Kyoon Kim, Campbell, CA (US); Bok Hoen Kim, San Jose, CA (US); Martin Jay Seamons, San Jose, CA (US); Francimar Campana Schmitt, Santa Clara, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/025,615

(22) Filed: Feb. 4, 2008

(51) Int. Cl. G03F 7/00; B05D 1/36; H05H 1/24; B32B 9/00

(52) U.S. Cl. 428/408; 427/402; 430/324; 427/569

(57) ABSTRACT

A method and structure for the fabrication of semiconductor devices having feature sizes in the range of 90 nm and smaller is provided. In one embodiment of the invention, a method is provided for processing a substrate including depositing an anti-reflective coating layer on a surface of the substrate, depositing an adhesion promotion layer on the anti-reflective coating layer, and depositing a resist material on the adhesion promotion layer. In another embodiment of the invention, a semiconductor substrate structure is provided including a dielectric substrate, an amorphous carbon layer deposited on the dielectric layer, an anti-reflective coating layer deposited on the amorphous carbon layer, an adhesion promotion layer deposited on the anti-reflective coating layer, and a resist material deposited on the adhesion promotion layer.

### BACKGROUND OF THE INVENTION

1. Field of the Invention

Embodiments of the present invention generally relate to the fabrication of substrates in the semi-conductor industry. In particular, the invention relates to a method of maintaining the adhesion of a resist to a surface during development of a pattern in the resist.

2. Description of the Background Art

Resist materials are used with patterning and etching techniques to form structures in materials deposited on substrates, whether the substrates and materials disposed thereon are used to fabricate circuit boards, flat panel displays, solar cells, or integrated circuits.

In particular, integrated circuit geometries have dramatically decreased in size since such devices were first introduced several decades ago. Since then, integrated circuits have generally followed the two year/half-size rule (often called Moore's Law), which means that the number of devices on a chip doubles every two years. Today's fabrication facilities are routinely producing devices having 90 nm and even 65 nm feature sizes, and tomorrow's facilities soon will be producing devices having even smaller feature sizes such as 45 nm and smaller.

As the feature sizes of integrated circuits decrease, so do the features of the photoresist material used to pattern the features into the integrated circuit. Photoresist material may be deposited, exposed, and then developed to create the photoresist pattern. When the development is immersion development, the developing solution may be rinsed from the integrated circuit with deionized water. With smaller features sizes, the adhesion force of the photoresist material to an antireflective coating (ARC) or even an adhesion promoting layer deposited on the ARC layer may approach the point where the capillary force of the drying water exceeds the adhesion force. When the capillary force exceeds the adhesion force, the pattern may collapse. When the pattern collapses, the integrated circuit will be defective because effective etching of features into the integrated circuit will not be performed.

A further problem in developing the photoresist occurs when certain portions of the resist, which have been exposed, may however not be completely removed as required and thus the structure may then not be correctly transferred into the underlying material during a subsequent etch process. The effect of insufficiently exposing and developing the photoresist is also referred to as resist poisoning. It is believed that a significant change of the resist sensitivity may be caused by an interaction of nitrogen and nitrogen radicals from nitrogen and/or nitrogen compounds present within a material stack with the resist layer, thereby locally blocking the photo acidic generator effect during exposure and post-exposure bake of the resist and thus locally modifying the resist structure after resist development (footing).

Therefore, there is a need in the art for a method of increasing the adhesion of the photoresist to the integrated circuit and reducing pattern collapsing in integrated circuits.

### SUMMARY OF THE INVENTION

The present invention generally relates to maintaining the adhesion of a resist to a surface during development of a pattern in the resist. In one embodiment of the invention, a method is provided for processing a substrate including depositing an anti-reflective coating layer on a surface of the substrate, depositing an adhesion promotion layer on the anti-reflective coating layer, and depositing a resist material on the adhesion promotion layer.

In another embodiment of the invention, a semiconductor substrate structure is provided including a dielectric substrate, an amorphous carbon layer deposited on the dielectric layer, an anti-reflective coating layer deposited on the amorphous carbon layer, an adhesion promotion layer deposited on the anti-reflective coating layer, and a resist material deposited on the adhesion promotion layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic illustration of an apparatus that may be used to practice embodiments of the invention.

FIGS. 2A-2D are schematic views of an integrated circuit 200 having a photoresist material formed thereon at various stages of processing according to one embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally relates to the fabrication of semiconductor devices having feature sizes in the range of 90 nm and smaller. In one embodiment of the invention, a method is provided for processing a substrate including depositing an anti-reflective coating (ARC) layer on a surface of the substrate, depositing an organic adhesion promotion layer on the ARC layer, and depositing a resist material on the adhesion promotion layer. The method may be used to improve adhesion of organic films to inorganic surfaces.

While the following description is directed to photoresist material, other resist material, such as e-beam resists, may be used with the invention described herein. The following description is also directed to feature sizes of about 45 nm or smaller, however, the invention is applicable to a variety of features and is also applicable to features sizes greater than 45 nm.

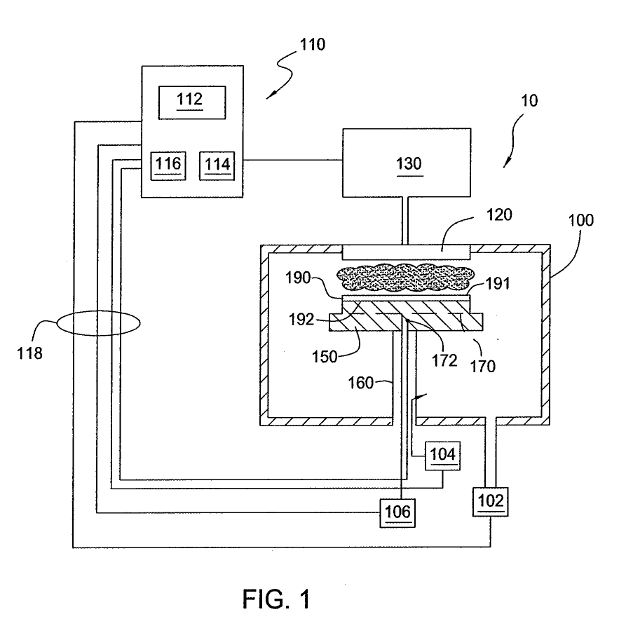

FIG. 1 illustrates schematic representation of a substrate processing system 10 that may be used to deposit ARC layers, such as nitrogen free ARC layers, and organic adhesion promotion layers, such as amorphous carbon layers. This system generally includes a process chamber 100, a gas panel 130, a control unit 110, and other hardware components, such as power supplies, vacuum pumps, etc. that are known in the art to be used to manufacture integrated circuit components. Examples of the system 10 include CENTURA® systems, PRECISION 5000® systems, and PRODUCER™ systems, all of which are commercially available from Applied Materials Inc., of Santa Clara, Calif.

The process chamber 100 generally includes a support pedestal 150, which is used to support a substrate, such as a semiconductor substrate 190. This pedestal 150 may typically be moved in a vertical direction inside the chamber 100 using a displacement mechanism 160. Depending on the specific process, the substrate 190 may be heated to a desired temperature by an embedded heating element 170 within pedestal 150. For example, the pedestal 150 may be resistively heated by applying an electric current from an power supply 106 to the heating element 170, which then heats the substrate 190. A temperature sensor 172, such as a thermocouple, for example, may be embedded in the substrate support pedestal 150 in order to monitor the temperature of the pedestal 150 through cooperative interaction with a process control system (not shown). The temperature read by the thermocouple may be used in a feedback loop to control the power supply 106 for the heating element 170 such that the substrate temperature can be maintained or controlled at a desired temperature that is suitable for the particular process application. Alternatively, the pedestal 150 may utilize alternative heating and/or cooling configurations known in the art, such as, plasma and/or radiant heating configurations or cooling channels (not shown).

A vacuum pump 102 may be used to evacuate the process chamber 100 and to maintain the desired gas flows and dynamic pressures inside the chamber 100. A showerhead 120, through which process gases may be introduced into the chamber 100, may be located above the substrate support pedestal 150. The showerhead 120 may generally be connected to a gas panel 130, which controls and supplies various gases used in different steps of the process sequence.

The showerhead 120 and substrate support pedestal 150 may also form a pair of spaced electrodes. Therefore, when an electric field is generated between these electrodes, the process gases introduced into the chamber 100 by the showerhead 120 may be ignited into a plasma, assuming that the potential between the spaced electrodes is sufficient to initiate and maintain the plasma. Typically, the RF power source is primarily coupled to the showerhead 120 through a matching network (not shown), or optionally, coupled to both the showerhead 120 and the substrate support pedestal 150 through respective matching networks. Alternatively, the driving electric field for the plasma is generated by connecting the substrate support pedestal 150 to a source of radio frequency (RF) power 104 through a matching network (not shown).

Plasma enhanced chemical vapor deposition (PECVD) techniques generally promote excitation and/or disassociation of the reactant gases by the application of the electric field to a reaction zone near the substrate surface, creating a plasma of reactive species immediately above the substrate surface. The reactivity of the species in the plasma reduces the energy required for a chemical reaction to take place, in effect lowering the required temperature for such PECVD processes.

In embodiments of the invention, ARC layers and organic adhesion promotion layers may deposited by plasma enhanced chemical vapor deposition processes. Deposition gases as described herein for the layers to be deposited may be introduced into the process chamber 100 under the control of the gas panel 130. The deposition gases may be introduced into the process chamber as a gas with a regulated flow through the showerhead 120.

Proper control and regulation of the gas flows through the gas panel 130 may be conducted by one or more mass flow controllers (not shown) and a control unit 110 such as a computer. The showerhead 120 allows process gases from the gas panel 130 to be uniformly distributed and introduced into the process chamber 100 proximate the surface of the substrate 190. Illustratively, the control unit 110 may include a central processing unit (CPU) 112, support circuitry 114, and various memory units containing associated control software 116 and/or process related data. Control unit 110 may be responsible for automated control over various steps required for substrate processing, such as substrate transport, gas flow control, temperature control, chamber evacuation, and other processes known in the art to be controlled by an electronic controller. Bi-directional communications between the control unit 110 and the various components of the apparatus 10 may be handled through numerous signal cables collectively referred to as signal buses 118, some of which are illustrated in FIG. 1.

The heated pedestal 150 used in the present invention may be manufactured from aluminum nitride or aluminum, and may include a heating element 170 embedded at a distance below the substrate support surface 192 of the pedestal 150. The heating element 170 may be manufactured from a nickel-chromium wire encapsulated in an INCOLOY® sheath tube. By properly adjusting the current supplied to the heating element 170, the substrate 190 and the pedestal 150 may be maintained at a relatively constant temperature during substrate preparation and film deposition processes. Proper adjustment of the current may be accomplished through a feedback control loop, in which the temperature of the pedestal 150 is continuously monitored by the temperature sensor 172 embedded in the pedestal 150. Information may be transmitted to the control unit 110 via a signal bus 118, which may respond by sending the necessary signals to the power supply 106. Adjustment may subsequently be made in the power supply 106 so as to maintain and control the pedestal 150 at a desirable temperature (i.e., a temperature that is appropriate for the specific process application). Therefore, when the process gas mixture exits the showerhead 120 above the substrate 190, plasma enhanced chemical vapor deposition of the hydrocarbon compound occurs at the surface 191 of the substrate 190, resulting in a deposition of an amorphous carbon layer on the substrate 190. Alternatively, the amorphous carbon material may be deposited by a thermal chemical vapor deposition method.

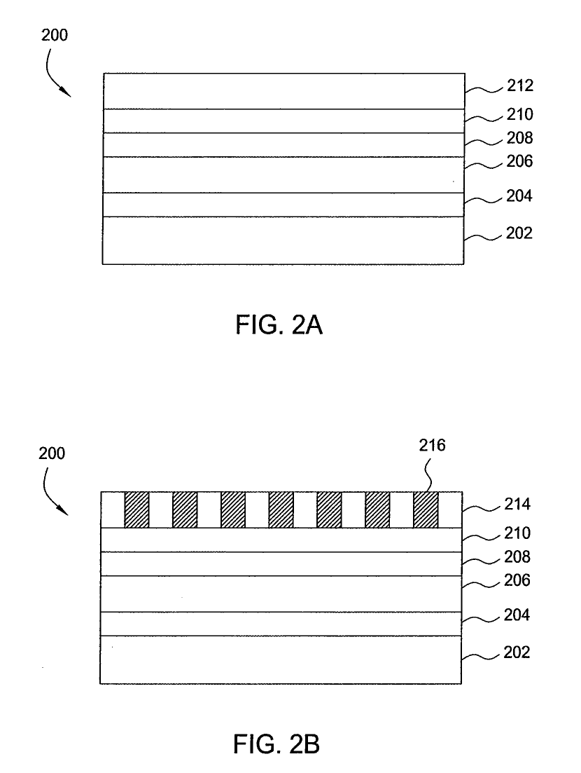

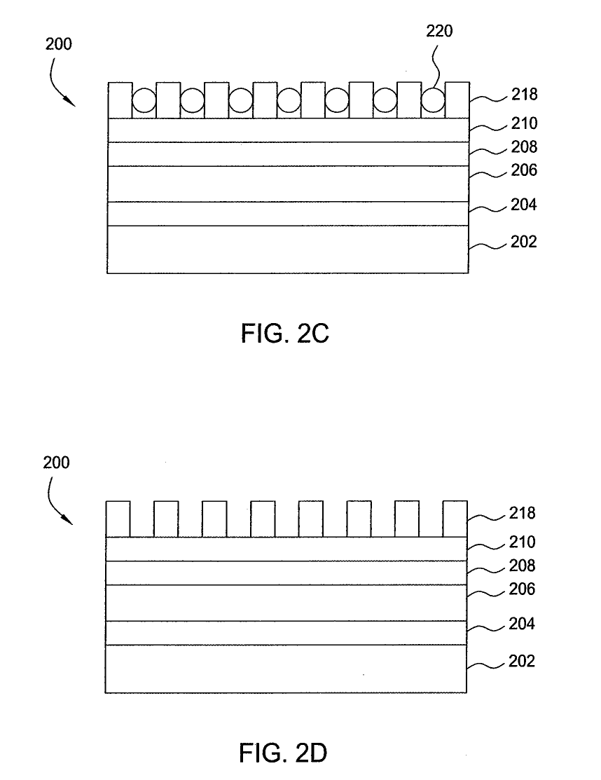

FIGS. 2A-2D are schematic views of an integrated circuit 200 having a photoresist material formed thereon at various stages of processing according to one embodiment of the invention. FIGS. 2A-2D illustrate one embodiment for processing a substrate including depositing an anti-reflective coating layer on a surface of the substrate, depositing an organic adhesion promotion layer on the anti-reflective coating layer, and depositing a photoresist material on the adhesion promotion layer.

As shown in FIG. 2A, the integrated circuit 200 may comprise a substrate 202. In general, the substrate 202 refers to any workpiece on which processing is performed. The substrate 202 may be part of a larger structure (not shown), such as a shallow trench isolation (STI) structure, a gate device for a transistor, a DRAM device, or a dual damascene structure. Depending on the specific stage of processing, the substrate 202 may correspond to a silicon substrate, or other material layer that has been formed on the substrate. FIG. 2A, for example, illustrates a cross-sectional view of an integrated circuit 200, having a material layer 204 that has been conventionally formed thereon. The material layer 204 may be an oxide (e.g., SiO₂). In general, the substrate 202 may include a layer of silicon, silicides, metals, or other materials. FIG. 2A illustrates one embodiment in which the substrate 202 is silicon having a material layer 204 of silicon dioxide formed thereon.

An amorphous carbon layer 206 may be deposited on the material layer 204. In one embodiment of the amorphous carbon layer, layer 206 may be deposited from a gas mixture of a hydrocarbon compound and an inert gas under reaction conditions. Amorphous carbon layers deposited by chemical vapor deposition (CVD) or plasma enhanced chemical vapor deposition (PECVD) methods may be used. An example of an amorphous carbon layer that may be used is an APF™ film, available from Applied Materials, Inc.

In one example of an amorphous carbon layer deposition process, the hydrocarbon compound general formula CₓH_{y} where x has a range of between 1 and 10 and y has a range of between 2 and 22. For example, methane (CH₄), ethane (C₂H₆), ethene (C₂H₄) propylene (C₃H₆), propyne (C₃H₄), propane (C₃H₈), butane (C₄H₁₀), butylene (C₄H₈), butadiene (C₄H₆), acetelyne (C₂H₂), pentane, pentene, pentadiene, cyclopentane, cyclopentadiene, benzene, toluene, alpha terpinene, phenol, cymene, norbornadiene, as well as combinations thereof, may be used as the hydrocarbon compound. Liquid precursors may be used to deposit amorphous carbon films. A variety of gases such as hydrogen (H₂) and ammonia (NH₃), or combinations thereof, among others, may be added to the gas mixture, if desired to control the hydrogen ratio of the amorphous carbon layer. Suitable inert gases include Argon (Ar), helium (He), and nitrogen (N₂), which may be used to control the density and deposition rate of the organic adhesion promotion layer.

In general, the following deposition process parameters may be used to form the amorphous carbon layer 206. The process parameters range from a substrate temperature of about 100 degrees Celsius to about 700 degrees Celsius, a chamber pressure of about 0.5 Torr to about 20 Torr, a hydrocarbon gas (CₓH_{y}) flow rate of about 50 sccm to about 50,000 sccm (per 12 inch substrate—for example), a RF power of between about 0.5 W/in² (0.07 cm²) to about 10 W/in² (1.6 W/cm²), and a plate spacing of between about 200 mils to about 1,200 mils. The thickness of the amorphous carbon layer 206 is variable, depending on the specific stage of processing. The amorphous carbon layer 206 may be deposited to a thickness in the range of about 100 Angstroms to about 20,000 Angstroms, such as between about 400 Angstroms to about 10,000 Angstroms. The above process parameters provide a typical deposition rate for the amorphous carbon layer in the range of about 100 Angstroms/min to about 20,000 Angstroms/min and may be implemented on a 300 mm substrate in a deposition chamber available from Applied Materials, Inc. of Santa Clara, Calif.

The amorphous carbon layer may be deposited by additional processes including amorphous carbon deposition processes described in commonly assigned U.S. Pat. No. 6,573,030, U.S. patent application Ser. No. 11/451,916, entitled “Methods for low temperature deposition of an amorphous carbon layer” and filed on Jun. 13, 2006, and U.S. patent application Ser. No. 11/427,324, entitled “Method for depositing an amorphous carbon film with improved density and step coverage” and filed on Jun. 28, 2006, which are herein incorporated by reference. A suitable amorphous carbon material is described in U.S. Pat. No. 6,541,397, issued on Apr. 1, 2003, which is incorporated by reference herein to the extent not inconsistent with the claims aspects and disclosure herein.

An ARC layer 208 may be deposited over the amorphous carbon layer 206 to suppress the reflections of the underlying layers and provide accurate pattern replication of the layer of photoresist. The ARC layer 208 may be conventionally formed on the amorphous carbon layer 206 using a variety of chemical vapor deposition (CVD) processes such as PECVD. In one embodiment, the ARC layer 208 may be graded. The ARC Layer 208 may be an inorganic nitrogen-free anti-reflective coating layer. The ARC Layer 208 may be a nitrogen-free material such as silicon carbide, silicon-rich oxide (SiₓO_{y}), or silicon oxycarbide SiOₓH_{y}:C or a nitrogen-containing material, such silicon nitride (SiₓN_{y}), silicon oxynitride (SiNₓO_{y}), hydrogenated silicon oxynitride, nitrogen doped silicon carbide, or nitrogen doped silicon oxycarbide. A combination of nitrogen-free material and nitrogen-containing material materials may be used to for the ARC layer including bi-layer ARC layers. Examples of suitable ARC Layer 208 materials are DARC® and DARC 193®, available from Applied Materials, Inc. and combinations thereof

The ARC layer 208 may be formed by generating a plasma of a gaseous mixture of a silicon source and at least one of a carbon source, a silicon source, an oxygen source, a nitrogen source, or combinations thereof, and, optionally, an inert gas. The silicon source may include silane, disilane, chlorosilane, dichlorosilane, trimethylsilane, tetramethylsilane, and combinations thereof. The silicon source may also include an organosilicon compounds such as tetraethoxysilane (TEOS), triethoxyfluorosilane (TEFS), diethoxymethylsilane (DEMS), 1,3,5,7-tetramethylcyclotetrasiloxane (TMCTS), dimethyldiethoxy silane (DMDE), octamethylcyclotetrasiloxane (OMCTS), and combinations thereof. The carbon source may be a hydrocarbon compound having a general formula CₓH_{y} where x has a range of between 2 and 10 and y has a range of between 2 and 22. Suitable hydrocarbon compounds may be selected from a group consisting of ethane (C₂H₆), ethene (C₂H₄), propylene (C₃H₆), propyne (C₃H₄), propane (C₃H₈), butane (C₄H₁₀), butylene (C₄H₈), butadiene (C₄H₆), acetelyne (C₂H₂), pentane, pentene, pentadiene, cyclopentane, cyclopentadiene, benzene, toluene, alpha terpinene, phenol, cymene, norbornadiene, and combinations thereof. Alternatively, the hydrocarbon compound may comprise methane, which may also be used in combination with one or more of the hydrocarbon compounds described herein. The nitrogen source may be ammonia (NH₃), nitrogen (N₂), or combinations thereof. The nitrogen and oxygen sources may be combined, such as when using nitrous oxide in the deposition gases. The inert gas may be selected from a group comprising argon, helium, neon, krypton, xenon, and combinations thereof.

In one embodiment, the gaseous mixture comprises silane at a flow rate between about 10 sccm and about 2,000 sccm, carbon dioxide at a flow rate between about 100 sccm and about 30,000 sccm, and helium at a flow rate between about 1 sccm and about 10,000 sccm. The varying optical properties of the ARC layer 208 are achieved by varying the flow rates of the aforementioned gases. The ARC layer 208 may have a refractive index (n) in the range of about 1.0 to 2.2 and an absorption coefficient (k) in the range of about 0 to about 1.0 at wavelengths less than about 250 nm, thus making it suitable for use as an ARC at DUV wavelengths. The ARC layer 208 may be deposited in a plasma-enhanced chemical vapor deposition process using a single 13.56 frequency RF power source or a dual frequency RF power source using a high frequency power at about 13.56 MHz and a low frequency power at between about 200 KHz and about 600 KHz, such as about 350 kHz, to generate a plasma.

The ARC Layer 208 may be deposited to a thickness of between about 1 Angstrom to about 3,000 Angstroms, including between about 50 Angstroms to about 800 Angstroms, for example, about 250 Angstroms.

In one embodiment, the amorphous carbon layer 206 and ARC layer 208 may be formed in situ in the same system or process chamber without breaking vacuum. The in situ ARC Layer 208 layer may be deposited under the same conditions as the amorphous carbon layer 206 but a silicon source, such as trimethylsilane or silane, is added followed by an oxygen precursor. Flow modulation of the gases in the chamber allows for graded deposition of the in situ layer.

While not shown, an optional oxide cap layer may be deposited on the ARC Layer 208 prior to deposition of an adhesion promotion layer 210. An oxide cap may be deposited between about 10 Angstroms and about 1,000 Angstroms, for example about 50 Angstroms thick. The oxide cap material may be silicon oxide, which, for example, may be generated from a processing gas of a silicon source, such as silane (SiH₄), an oxygen source such as carbon dioxide (CO₂) or nirous oxide (N₂O), and an optional inert gas, such as helium, in a single frequency plasma deposition process.

To reduce or prevent photoresist material pattern collapse, an organic adhesion promotion layer (APL) 210 is deposited on the ARC layer 208.

The organic adhesion promotion layer 210 may include a material having a wetting angle of greater than 450, such as between about 450 and about 700, such as about 60°. One embodiment of the organic adhesion promotion material may have a wetting angle of the same or similar wetting angle, i.e., ±100, as the photoresist material. The wetting angle is the contact angle between a surface and a droplet located between a horizontal substrate surface and a tangent drawn along the curvature of the droplet at the edge of droplet.

Additionally, the organic adhesion promotion layer 210 may be a non-polar material and in one embodiment may have the same or similar non-polar characteristics as a photoresist material. Further, the organic adhesion promotion layer 210 may be a hydrophobic material and in one embodiment may have the same or similar hydrophobic characteristics as a photoresist material. Additionally, the organic adhesion promotion layer 210 may perform as a barrier material to reduce or eliminate nitrogen and nitrogen radical migration through the dielectric material stack, thereby limiting exposure of the photoresist to nitrogen and nitrogen radicals and reduce or eliminate resist poisoning.

The organic adhesion promotion layer 210 preferably comprises a material having one or more carbon single bonds (C—C), one or more carbon double bonds (C═C), or combination thereof. It is believed that the carbon single bonds (C—C), one or more carbon double bonds (C—C) react with photoresist material to form carbon-carbon chemical bonds between the photoresist material and the organic adhesion promotion layer material, thereby increasing adhesion between the two materials. The reaction may be a base (OH—) catalyzed reaction, such as from a photoresist developer (CH₃)₄N⁺OH—.

In one embodiment, the organic adhesion promotion layer 210 may comprise amorphous carbon. The organic adhesion promotion layer 210 may be formed by the amorphous carbon deposition processes described above for the amorphous carbon layer 206. In one example of an amorphous carbon deposition process, the organic adhesion promotion layer 210 may be formed by introducing a hydrocarbon compound and an inert gas into the processing chamber. The hydrocarbon compound may have a general formula CₓH_{y} where x has a range of between 2 and 10 and y has a range of between 2 and 22, for example, ethane (C₂H₆), ethene (C₂H₄), propylene (C₃H₆), propyne (C₃H₄), propane (C₃H₈), butane (C₄H₁₀), butylene (C₄H₈), butadiene (C₄H₆), acetelyne (C₂H₂), pentane, pentene, pentadiene, cyclopentane, cyclopentadiene, benzene, toluene, alpha terpinene, phenol, cymene, norbornadiene, and combinations thereof, and the inert gases may include Argon (Ar), helium (He), nitrogen (N₂), and combinations thereof. Alternatively, the hydrocarbon compound may comprise methane, which may also be used in combination with one or more of the hydrocarbon compounds described herein. The hydrocarbon compound may be introduced to the processing chamber at a rate between about 100 sccm and about 5,000 sccm and the inert gas may be introduced to the processing chamber at a rate between about 100 sccm and about 10,000 sccm.

The organic adhesion promotion layer 210 may be deposited utilizing either a single frequency RF bias to the showerhead or a dual frequency bias where both the showerhead and the substrate support are biased. In a single frequency process, the RF current may be applied at about 13.56 MHz at a power level between about 100 watts and about 2,000 watts. The organic adhesion promotion layer 210 may be deposited to a thickness of between about 1 Angstrom to about 3,000 Angstroms, including between about 5 Angstroms to about 100 Angstroms, such as a thickness between about 10 Angstroms and about 20 Angstroms.

The organic adhesion promotion layer 210 may be deposited in situ within the same chamber or same processing system as the ARC layer 208, the amorphous carbon layer 206, or both layers 206, 208. The in situ organic adhesion promotion layer 210 layer may be deposited under the same conditions as the ARC layer 208 with a silicon source of the ARC Layer 208 being terminated for the organic adhesion promotion layer 210 deposition process.

Additionally, the organic adhesion promotion layer may include a spin-on organic dielectric material, such as a polymeric material, for example, fluorinated and non-fluorinated poly(arylene)ethers (commercially known as FLARE 1.0 and 2.0, which are available from Allied Signal Company), poly(arylene)ethers (commercially known as PAE 2-3, available from Schumacher Company), divinyl siloxane benzocyclobutane (DVS-BCB) or similar products and aero-gel.

In an alternative embodiment of the invention, an amorphous silicon material may be deposited on the ARC Layer 208 instead of the organic adhesion promotion layer 210. The amorphous silicon layer may be deposited in situ with the ARC Layer 208 in the same chamber.

After depositing the organic adhesion promotion layer 210, the organic adhesion promotion layer 210 may be exposed to an optional adhesion promoter material, such as hexamethyidisilizane (HMDS), which serves to bond the photoresist material 212 to the organic adhesion promotion layer 210. The photoresist material 212 may be a chemically amplified positive photoresist material which produces an acid in pattern areas of the photoresist material which are to be removed upon development. Photoresist materials may comprise polymeric based materials having carbon-carbon bonds, and may be deposited by spin-on processes. The adhesion promotion layer may be used with photoresist materials, e-beam resist materials, or other materials requiring improved adhesion between organic films and inorganic materials or surfaces.

As shown in FIGS. 2B-2C, the photoresist material 212 may be pattern exposed to create exposed regions 216 and unexposed regions 214 in the photoresist material 212 as shown in FIG. 2B that are removed by development as shown in FIG. 2C. While the photoresist exemplified in the drawings is a positive photoresist whereby the exposed portions are removed, it is to be understood that a negative photoresist may be used whereby unexposed portions of the photoresist may be removed during development. After development, the developing solution may be removed by deionized water 220 to form the structure as shown in FIG. 2D. Thereafter, the pattern defined by the features 218 may be transferred through the organic adhesion promotion layer 210, the ARC layer 208 and the amorphous carbon layer 206 in one or more etching steps.

In situ should be broadly construed and includes, but is not limited to, in a given chamber, such as in a plasma chamber, or in a system, such as an integrated cluster tool arrangement, without exposing the material to intervening contamination environments, such as breaking vacuum between process steps or chambers within a tool. An in situ process typically minimizes process time and possible contaminants compared to relocating the substrate to other processing chambers or areas.

### EXAMPLE 1

An amorphous carbon layer adhesion promotion layer was deposited over a substrate having a layer stack consisting of a material layer, an amorphous carbon layer, and an ARC layer. One embodiment of the adhesion promotion layer deposition process includes introducing process gases of propylene at a flow rates of about 100 sccm and helium at a flow rate of about 2000 sccm into a processing chamber maintained at a temperature between 350° C. and 400° C. and a pressure of about 5 Torr, and applying (biasing) a power level of about 250 watts with an RF frequency of 13.56 MHz to a showerhead disposed at about 380 mils from the substrate surface. The amorphous carbon layer adhesion promotion layer was deposited to a thickness of about 10 to about 20 Angstroms.

While the foregoing is directed to embodiments of the present invention, other and further embodiments of the invention may be devised without departing from the basic scope thereof, and the scope thereof is determined by the claims that follow.

What is claimed is:

1. A method of processing a substrate comprising:
depositing an anti-reflective coating layer on a surface of the substrate;
depositing an organic adhesion promotion layer on the anti-reflective coating layer; and
depositing a resist material on the organic adhesion promotion layer.

2. The method of claim 1, further comprising developing the resist material.

3. The method of claim 1, wherein the resist material comprises a chemically amplified positive resist material.

4. The method of claim 1, wherein the anti-reflective coating layer comprises a dielectric anti-reflective material selected from the group consisting of silicon-rich oxide, silicon nitride, silicon oxynitride, silicon carbide, silicon oxycarbide, nitrogen doped silicon carbide, nitrogen doped silicon oxycarbide, and combinations thereof.

5. The method of claim 1, wherein the organic adhesion promotion layer comprises an amorphous carbon material.

6. The method of claim 1, wherein the substrate surface further comprises an amorphous carbon layer and the anti-reflective coating layer is deposited on the amorphous carbon layer.

7. The method of claim 1, further comprising depositing an oxide cap layer on the anti-reflective coating layer prior to deposition of the organic adhesion promotion layer.

8. The method of claim 1, wherein the organic adhesion promotion layer is deposited by plasma-enhanced chemical vapor deposition of a hydrocarbon precursor.

9. The method of claim 1, further comprising exposing the organic adhesion promotion layer to hexamethyl disilazane prior to deposition of the resist material.

10. The method of claim 2, wherein the developing the resist material comprises:
pattern exposing the resist;
immersion developing the resist to create a resist material; and
drying the resist material.

11. The method of claim 1, wherein the organic adhesion promotion layer has a carbOn-carbon single bond, a carbon-carbon double bond, or combinations thereof.

12. The method of claim 1, wherein the anti-reflective coating layer and the organic adhesion promotion layer are deposited in situ within the same processing chamber or processing system.

13. The method of claim 1, further comprising exposing the organic adhesion promotion layer to hexamethyl disilazane prior to deposition of the resist material.

14. A semiconductor substrate structure comprising:
a dielectric substrate;
an amorphous carbon layer deposited on the dielectric layer;
an anti-reflective coating layer deposited on the amorphous carbon layer;
an organic adhesion promotion layer deposited on the anti-reflective coating layer; and
a resist material deposited on the organic adhesion promotion layer.

15. The semiconductor substrate structure of claim 14, further comprising a hexamethyl disilazane material formed between the organic adhesion promotion layer and the resist material.

16. The semiconductor substrate structure of claim 14, wherein the resist material comprises a chemically amplified positive resist material.

17. The semiconductor substrate structure of claim 14, wherein the anti-reflective coating layer comprises a plasma-enhanced chemical vapor deposition anti-reflective material.

18. The semiconductor substrate structure of claim 14, wherein the organic adhesion promotion layer comprises an amorphous carbon material.

19. The semiconductor substrate structure of claim 14, further comprising an oxide cap layer disposed between the anti-reflective coating layer and the organic adhesion promotion layer.

20. The semiconductor substrate structure of claim 14, wherein the organic adhesion promotion layer has a carbon-carbon single bond, a carbon-carbon double bond, or combinations thereof.
